(19) United States
(12) Patent Application Publication
(10) Pub. No.: US 2013/0134538 A1
(43) Pub. Date: May 30, 2013

(54) SOLID-STATE IMAGING DEVICE

(71) Applicants: Maki SATO, Kanagawa (JP); Koichi Kokubun, Kanagawa (JP)

(72) Inventors: Maki SATO, Kanagawa (JP); Koichi Kokubun, Kanagawa (JP)

(21) Appl. No.: 13/680,946

(22) Filed: Nov. 19, 2012

(30) Foreign Application Priority Data
Nov. 25, 2011 (JP) 2011-257441

(51) Int. Cl. H01L 31/0232; H01L 31/18

(52) U.S. Cl. CPC H01L 31/0232; H01L 31/18
USPC 257/432; 438/70

(57) ABSTRACT

According to an embodiment, an image sensor is provided for photoelectrically converting blue light, green light and red light for each pixel. A photoelectric conversion layer for red light is provided having a light absorption coefficient that is different than the light absorption coefficient of the photoelectric conversion layers for blue light and green light.

### CROSS-REFERENCE TO RELATED APPLICATION

This application is based upon and claims the benefit of priority from Japanese Patent Application No. 2011-257441, filed Nov. 25, 2011; the entire contents of which are incorporated herein by reference.

### FIELD

Embodiments described herein relate generally to a solid-state imaging device.

### BACKGROUND

In a solid-state imaging device, incident light is separated into the three primary colors (e.g., red, green and blue). The corresponding signals of each color is retrieved and the captured image will be reproduced in corresponding colors. In some cases, the colors are mixed and lack a sharp contrast in the reproduced image. Forming photodiodes at a shallow depth may prevent the mixture of colors in the imaging device. However, shallow photodiodes may cause a great decrease in sensitivity, particularly with light having long wavelengths.

Therefore, what is needed is an imaging device that overcomes the inadequacies of conventional image sensors.

### DESCRIPTION OF THE DRAWINGS

FIG. 1 is a cross-sectional view showing the schematic configurations of a solid-state imaging device according to one embodiment.

FIG. 2A is a schematic cross-sectional view of the image sensor of FIG. 1 for blue.

FIG. 2B is a schematic cross-sectional view of the image sensor of FIG. 1 for green.

FIG. 2C is a c schematic cross-sectional view of the image sensor of FIG. 1 for red.

FIG. 3 is a graph showing the relationship in terms of wavelengths and intensity among blue light, green light and red light.

FIG. 4 is a graph showing the absorption coefficients of the wavelengths of different semiconductor materials.

FIG. 5A to FIG. 5C are cross-sectional views showing one embodiment of a manufacturing method for the image sensor of FIG. 2A for blue.

FIG. 6A and FIG. 6B are cross-sectional views showing further aspects of the manufacturing method for the image sensor of FIG. 2A for blue.

FIG. 7A to FIG. 7C are cross-sectional views showing one embodiment of a manufacturing method of the image sensor of FIG. 2A for red.

FIG. 8A and FIG. 8B are cross-sectional views showing further aspects of a manufacturing method of the image sensor of FIG. 2A for red.

FIG. 9A is a schematic cross-sectional view showing another embodiment of an image sensor for blue color that may be used with the solid-state imaging device of FIG. 1.

FIG. 9B is a schematic cross-sectional view showing another embodiment of an image sensor for green color that may be used with the solid-state imaging device of FIG. 1.

FIG. 9C is schematic a cross-sectional view showing another embodiment of an image sensor for red color that may be used with the solid-state imaging device of FIG. 1.

FIG. 10 is a schematic cross-sectional view showing another embodiment of an image sensor that may be used with the solid-state imaging device of FIG. 1.

FIG. 11A to FIG. 11D are cross-sectional views showing an embodiment of a manufacturing method for the image sensor of FIG. 10.

FIG. 12A to FIG. 12C are cross-sectional views showing further aspects of a manufacturing method for the image sensor of FIG. 10.

FIG. 13 is a schematic cross-sectional view showing another embodiment of an image sensor that may be used with the solid-state imaging device of FIG. 1.

### DETAILED DESCRIPTION

In general, embodiments of a solid-state imaging device are described herein by referring to the drawings as follows. It should be noted that the invention is not limited to these embodiments.

According to the embodiments, there is provided a solid-state imaging device that enables a reduction of the mixture of colors while maximizing sensitivity.

The solid-state imaging device representing this embodiment is provided with a wavelength separator, a first image sensor and a second image sensor. The wavelength separator separates incident light into individual colors. The first image sensor performs, in individual pixels, the photoelectric conversion of the first colored light that has been separated by the wavelength separator. The second image sensor is provided with a photoelectric conversion unit for each pixel with a different absorption coefficient from the first image sensor and performs, in individual pixels, the photoelectric conversion of the second colored light that has been separated by the wavelength separator.

### First Embodiment

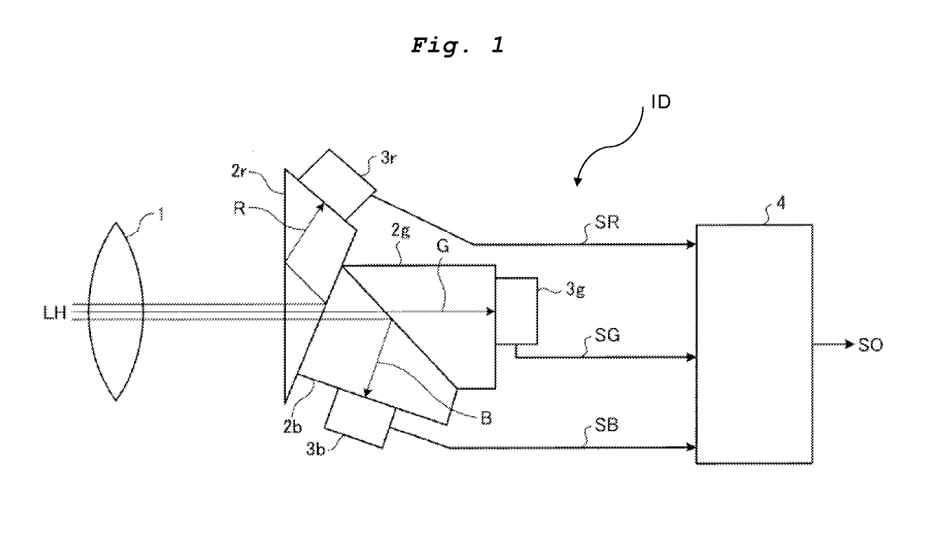

FIG. 1 is a cross-sectional view showing the schematic configurations of a solid-state imaging device ID according to one embodiment. Also, the imaging device ID of FIG. 1 shows an example of a three-plate type solid-state imaging device.

The solid-state imaging device ID includes a lens 1, which transmits incident light LH, dichroic prisms 2b, 2g and 2r, which respectively separate incident light LH into blue light B, green light G and red light R. Collectively, the dichroic prisms 2b, 2g and 2r comprise a wavelength separator that functions as a demultiplexer for blue light B, green light G and red light R. The solid-state imaging device ID also includes an image sensor 3b for blue color, which performs a photoelectric conversion of blue light B into individual pixels, an image sensor 3g for green color, which performs a photoelectric conversion of green light G into individual pixels, an image sensor 3r for red color, which performs a photoelectric conversion of red color R into individual pixels, and a signal processing unit 4. The signal processing unit 4 generates a color image signal SO by synthesizing blue image signal SB, green image signal SG and red image signal SR.

The solid-state imaging device ID includes a photoelectric conversion unit of the image sensor 3r for red color, a photoelectric conversion unit of the image sensor 3b for blue color and a photoelectric conversion unit of the image sensor 3g for green color. Each photoelectric conversion unit may be formed by different materials according to their different absorption coefficients of light.

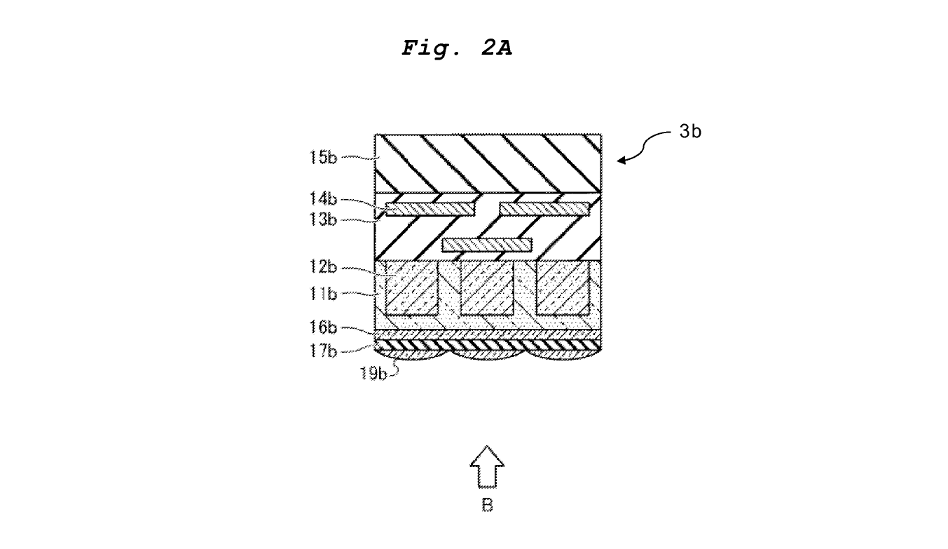

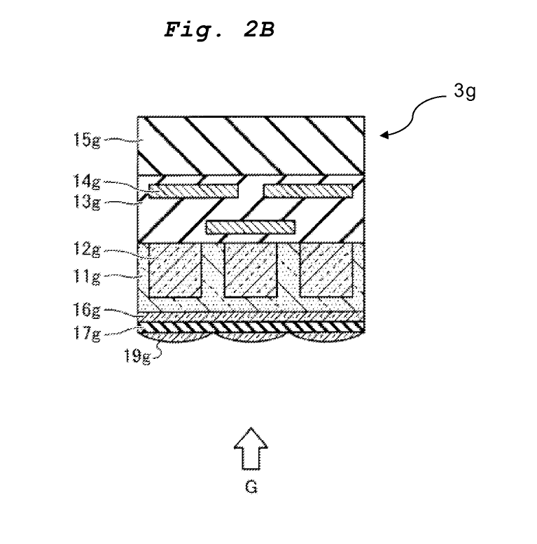

FIG. 2A is a cross-sectional view showing the schematic configurations of the image sensor 3b for blue color in FIG. 1, FIG. 2B is a cross-sectional view showing the schematic configurations of the image sensor 3g for green color in FIG. 1 and FIG. 2C is a cross-sectional view showing the schematic configurations of the image sensor 3r for red color in FIG. 1. It should be noted that in FIG. 2A to FIG. 2C the examples of the image sensors may be used as a back-illuminated type image sensor.

In FIG. 2A, on the image sensor 3b for blue color, a semiconductor layer 11b is provided. The semiconductor layer 11b may use, for example, silicon (Si) as its material. Also, for the semiconductor layer 11b, a P-type epitaxial semiconductor may be used. On the surface of the semiconductor layer 11b, a photoelectric converting layer 12b is formed in individual pixels in the semiconductor layer 11b. An interlayer insulating layer 13b is formed on the semiconductor layer 11b. It should be noted that the conductivity type of the photoelectric converting layer 12b may be set as N type. The interlayer insulating layer 13b may be made of, for example, silicon oxide (SiO₂) film. The thickness of the semiconductor layer 11b may be provided such that the electrical charges that are photoelectrically converted by one of the photoelectric converting layer 12b of the pixels of semiconductor layer 11b do not flow into the photoelectric converting layer 12b of other pixels of semiconductor layer 11b.

On the interlayer insulating layer 13b, a wiring layer 14b is embedded. It should be noted that, on the back-illuminated type image sensor, the wiring layer 14b may be formed on the photoelectric converting layer 12b. The wiring layer 14b may be made of metals such as aluminum (Al) or copper (Cu). Also, the wiring layer 14b may select the pixels to read out or transmit the signals that have been read from the pixels. On the interlayer insulating layer 13b, a supporting substrate 15b, which supports the semiconductor layer 11b, is provided. The supporting substrate 15b may be made of a semiconductor substrate such as Si or of an insulating substrate such as glass, ceramic or resin.

On the opposite side of the semiconductor layer 11b, a pinning layer 16b is formed, and on the pinning layer 16b, an antireflection film 17b is formed. It should be noted that the pinning layer 16b may use a P-type doping layer formed in the semiconductor layer 11b. The antireflection film 17b may use a laminated structure of silicon oxide films that have different refractive indices. On the top (i.e., light-incident side) of the antireflection film 17b, an on-chip lens 19b is formed in individual pixels. The on-chip lens 19b may be fabricated from, for example, transparent organic compounds, such as acrylic or polycarbonate material.

FIG. 2B shows that, on the image sensor 3g for green color, a semiconductor layer 11g is provided. A photoelectric converting layer 12g is formed in individual pixels in the semiconductor layer 11g. An interlayer insulating layer 13g is formed on the semiconductor layer 11g. The thickness of semiconductor layer 11g may be provided to minimize or eliminate cross-talk of electrical charges between pixels in the photoelectric converting layer 12g. In the interlayer insulating layer 13g, a wiring layer 14g is embedded. A supporting substrate 15g is formed on the insulating layer 13g, which supports the semiconductor layer 11g.

On the opposing side (i.e., light-incident side) of the semiconductor layer 11g, a pinning layer 16g is formed, and on the pinning layer 16g, an antireflection film 17g is formed. On the top (i.e., light-incident side) of the antireflection film 17g, an on-chip lens 19g is formed in individual pixels.

It should be noted that the semiconductor layer 11g, the photoelectric converting layer 12g, the interlayer insulating layer 13g, the wiring layer 14g, the supporting substrate 15g, the pinning layer 16g, the antireflection film 17g and the on-chip lens 19g may respectively use the same materials as the semiconductor layer 11b, the photoelectric converting layer 12b, the interlayer insulating layer 13b, the wiring layer 14b, the supporting substrate 15b, the pinning layer 16b, the antireflection film 17b and the on-chip lens 19b.

FIG. 2C shows that, on the image sensor 3r for red color, a semiconductor layer 11r is provided, and on the semiconductor layer 11r, an alloy semiconductor layer 11r′ is laminated. The alloy semiconductor layer 11r′ may use materials that have a higher light absorption coefficient than those of the semiconductor layer 11r, for example, silicon germanium (SiGe). It should be noted that in order to take the lattice matching between Si and SiGe, the content of Ge in SiGe is more than 0% and less than about 30%. Also, as the semiconductor layer 11r′, it is possible to use a P-type epitaxial semiconductor.

A photoelectric converting layer 12r is formed in individual pixels in the alloy semiconductor layer 11r′, and an interlayer insulating layer 13r is formed on the semiconductor layer 11r′. It should be noted that the thicknesses of the semiconductor layers 11r and 11r′ may be provided to minimize or eliminate cross-talk of electrical charges between pixels in the semiconductor layer 12r. In the interlayer insulating layer 13r, a wiring layer 14r is embedded. A supporting substrate 15r is formed on the interlayer insulating layer 13r, which supports the semiconductor layers 11r and 11r′.

On the opposing side of the semiconductor layer 11r, a pinning layer 16r is formed, and on the pinning layer 16r, an antireflection film 17r is formed. On the top (i.e., light-incident side) of the antireflection film 17r, an on-chip lens 19r is formed in individual pixels.

It should be noted that the semiconductor layer 11r, the photoelectric converting layer 12r, the interlayer insulating layer 13r, the wiring layer 14r, the supporting substrate 15r, the pinning layer 16r, the antireflection film 17r and the on-chip lens 19r may respectively use the same materials as the semiconductor layer 11b, the photoelectric converting layer 12b, the interlayer insulating layer 13b, the wiring layer 14b, the supporting substrate 15b, the pinning layer 16b, the antireflection film 17b and the on-chip lens 19b.

Also, in the structure of FIG. 2C, in order to form the photoelectric converting layer 12r, the techniques using the two-layer structure—the semiconductor layer 11r and the alloy semiconductor layer 11r′ is shown, but it is also possible to use a single layer structure, for example, the alloy semiconductor layer 11r′ only.

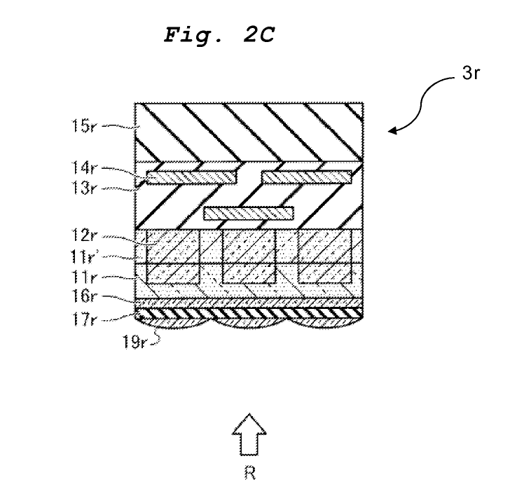

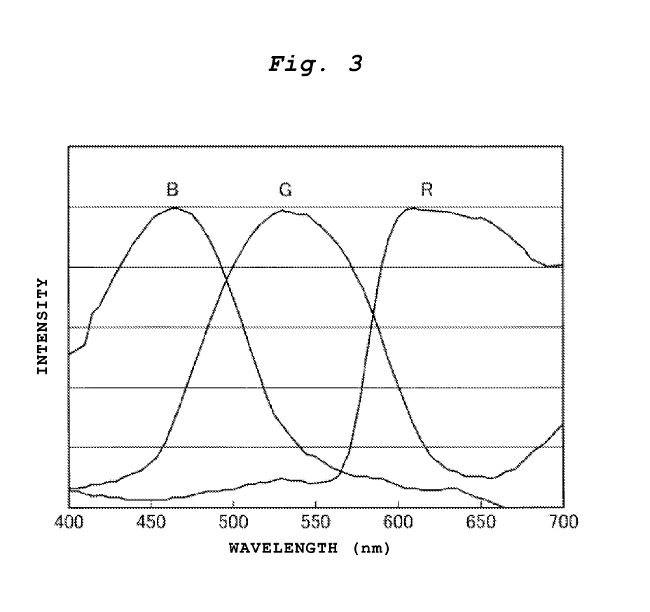

FIG. 3 is a graph showing the relationship between the wavelengths and the intensity of the blue light B, the green light G and the red light R. FIG. 3 shows that the blue light B has a peak of intensity at about 450 nm wavelength, the green light G has a peak of intensity at about 530 nm wavelength and the red light R has a peak of intensity at about 600 nm wavelength.

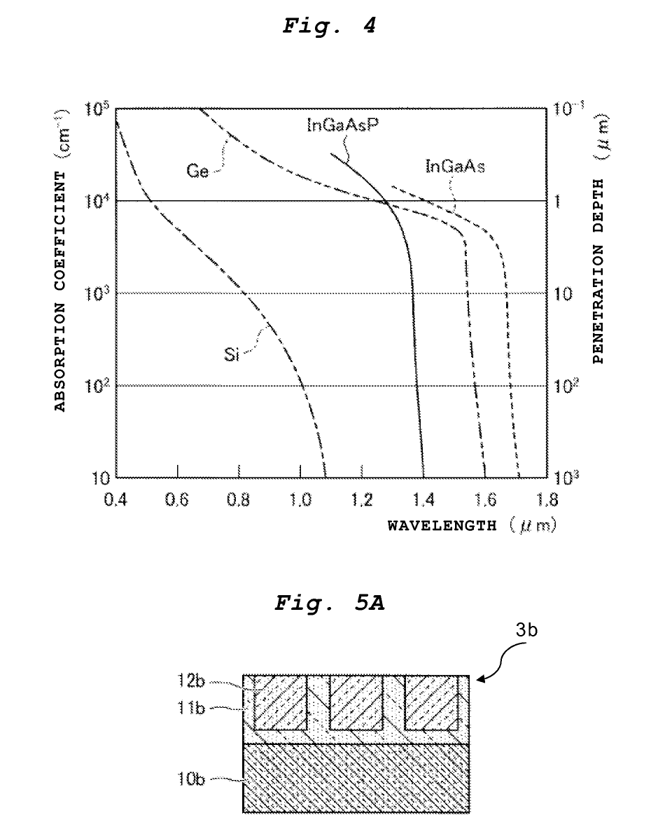

FIG. 4 shows light absorption coefficients according to the wavelengths of each semiconductor material.

FIG. 4 shows that Ge has a higher light absorption coefficient than Si. Consequently, it is possible to improve the photoelectric conversion efficiency by using varying percentages of Ge with Si instead of complete Si.

FIG. 1 shows that, when the incident light LH enters the dichroic prisms 2b, 2g and 2r through the lens 1, it is separated into the blue light B, the green light G and the red light R. The blue light B is incident on the image sensor 3b for blue color, green light G is incident on the image sensor 3g for green color and the red light R is incident on the image sensor 3r for red color. In the image sensor 3b for blue color, the blue image signal SB is generated by photoelectrically converting the blue light B into individual pixels and sent to the signal processing unit 4. In the image sensor 3g for green color, the green image signal SG is generated by photoelectrically converting the green light G into individual pixels and sent to the signal processing unit 4. And in the image sensor 3r for red color, the red image signal SR is generated by photoelectrically converting red light R into individual pixels and sent to the signal processing unit 4. After that, in the signal processing unit 4, the blue image signal SB, the green image signal SG and the red image signal SR are synthesized and output as the color image signal SO.

Here, by using the alloy semiconductor layer 11r′ to form the photoelectric converting layer 12r, it is possible to improve the photoelectric conversion efficiency of the photoelectric converting layer 12r. The photoelectric conversion efficiency is higher than when forming the photoelectric converting layer 12r using the alloy semiconductor layer 11r′ as opposed to using only the semiconductor layer 11r. When using the alloy semiconductor layer 11r′ it is possible to reduce the depth of the photoelectric converting layer 12r, while also suppressing a decrease in sensitivity of the image sensor 3r for red color. This enables an increase in resolution when using the alloy semiconductor layer 11r′ at a shallower depth as it becomes possible to minimize the interference of diagonally incident red light R to adjacent pixels.

On the other hand, as the blue light B and the green light G have shorter wavelengths than the red light R, these shorter wavelengths reach the depth of the photoelectric converting layers 12b and 12g. By reducing the depth of the photoelectric layers 12b and 12g in order to minimize the depth of the photoelectric converting layer 12r, it is also possible to suppress decreases in sensitivity of the image sensor 3b for blue color as well as the image sensor 3g for green color.

For example, SiGe has a higher light absorption coefficient than Si. Because of this, by using SiGe as the semiconductor layer 11r′, it is possible to form a photodiode as an entire image sensor with a shallow junction. More precisely, the depth of the junction of a photodiode, which represents the whole image sensor considering that the penetration depth of Si in the red light R is about 3.0 μm, in order to achieve equivalent sensitivity as when using SiGe, it is possible to set the depth of the junction of the photodiode to about 1.5 μm. This enables the suppression of a decrease in resolution as it becomes possible to suppress the interference of red light R diagonally incident to adjacent pixels.

It should be noted that FIG. 2A to 2C indicate that the technique in which the blue color B, the green color G and the red color R are respectively incident into the image sensor 3b for blue color, the image sensor 3g for green color and the image sensor 3r for red color has been explained. However, it is also possible to separate the wavelengths by splitting the incident light LH into the image sensor 3b for blue color, the image sensor 3g for green color and the image sensor 3r for red color using filters. In this case, in order to extract the blue light B, the green light G and the red light R from the incident light LH, it is possible to provide blue, green and red transmission filters, respectively, on the image sensor 3b for blue color, the image sensor 3g for green color and the image sensor 3r for red color.

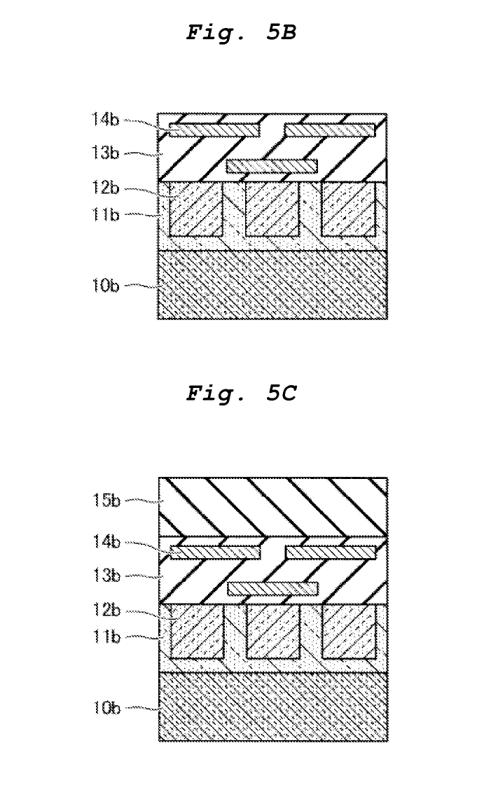

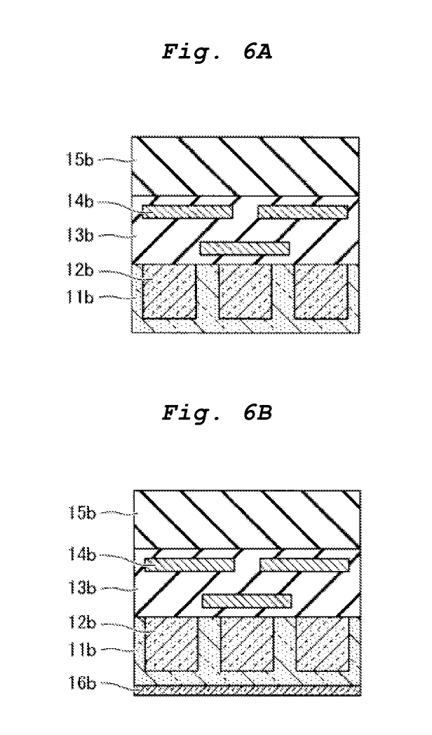

FIG. 5A to FIG. 5C and FIG. 6A and FIG. 6B are cross-sectional views of the image sensor 3b for blue color of FIG. 2A that describe another embodiment of a manufacturing method thereof. It should be noted that, for this explanation, the formation of gate electrodes is omitted for brevity.

FIG. 5A shows that the semiconductor layer 11b is formed on a semiconductor substrate 10b by epitaxial growth. It should be noted that, if the semiconductor layer 11b is made of Si, then the semiconductor substrate 10b is made of Si as well. In this case, P-type impurities such as boron (B) may be doped by the semiconductor layer 11b.

After that, using selective implantation of impurities in individual pixels on the semiconductor layer 11b by photolithography and ion implantation techniques, the photoelectric converting layer 12b is formed in individual pixels on the semiconductor layer 11b. It should be noted that N-type impurities, such as phosphorus (P) or arsenic (As) may be used.

The next step, as shown in FIG. 5B, is to form the wiring layer 14b, which is embedded in the interlayer insulating layer 13b on the semiconductor layer 11b.

As shown in FIG. 5C, on the interlayer insulating layer 13b, the supporting substrate 15b is adhered. It should be noted that, for example, direct bonding with SiO₂ may be used as a technique for adhering the supporting substrate 15b on the interlayer insulating layer 13b.

The next step, as shown in FIG. 6A, is to remove the semiconductor substrate 10b from the semiconductor layer 11b by using CMP or etch-back techniques.

As shown in FIG. 6B, due to the ion implantation in high concentrations of impurities on the semiconductor layer 11b, a pinning layer 16b is formed thereon. It should be noted that impurities at this stage may be, for example, P-type impurities such as boron (B). Also, by the epitaxial growth that has been doped by P-type impurities in high concentration, it is also good to form the pinning layer 16b on the back side of the semiconductor layer 11b.

Referring back to FIG. 2A, the next step is to form the on-chip lens 19b in individual pixels after forming the antireflection film 17b on the pinning layer 16b.

It should be noted that the manufacturing method of the image sensor 3g for green color is the same as the manufacturing method of the image sensor 3b for blue color.

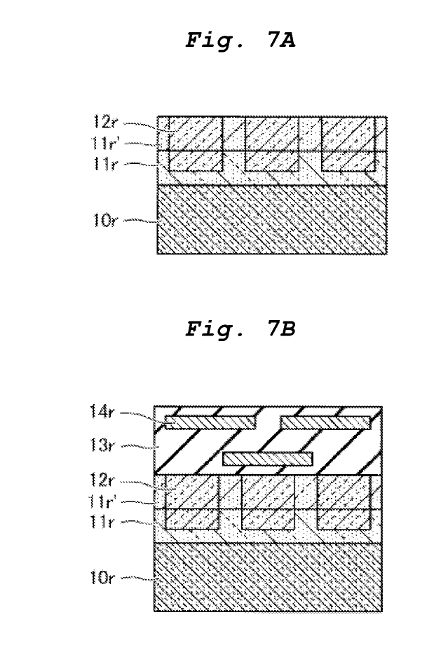

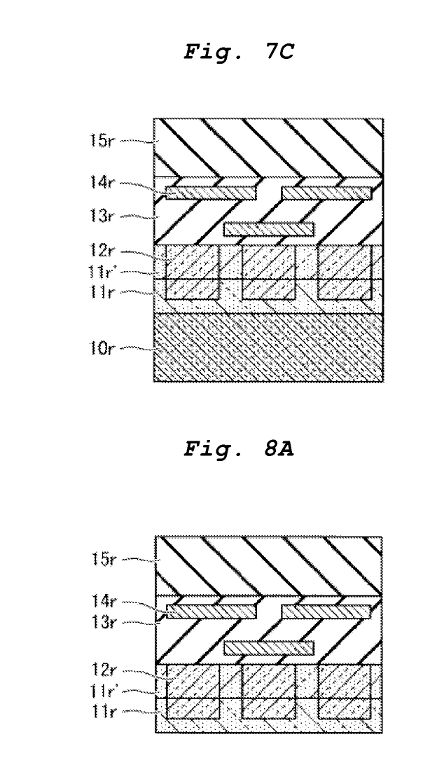

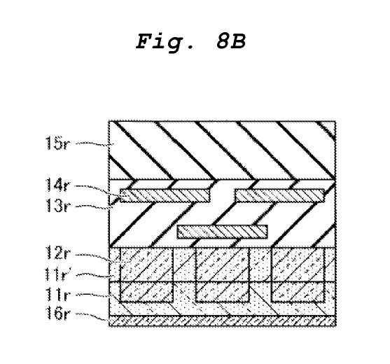

FIG. 7A to FIG. 7C and FIG. 8A and FIG. 8B are cross-sectional views showing another embodiment of a manufacturing method for the image sensor 3r for red color shown in FIG. 2A. It should be noted that this explanation omits the forming process of gate electrodes for brevity.

FIG. 7A shows that the semiconductor layers 11r and 11r′ are sequentially formed on a semiconductor substrate 10r by epitaxial growth. It should be noted that it is possible to use Si as the semiconductor substrate 10r and the semiconductor layer 11r and to use SiGe as the semiconductor layer 11r′. At this stage, it is possible to dope P-type impurities such as B to form the semiconductor layer 11r or 11r′. It is also possible to omit the semiconductor layer 11r and form the alloy semiconductor layer 11r′ directly on the semiconductor substrate 10r.

After that, by using photolithography and ion implantation techniques for selective implantation of impurities in individual pixels on the semiconductor layers 11r and 11r′, the photoelectric converting layer 12r is formed, in individual pixels, on the semiconductor layer 11r′. It should be noted that impurities on the semiconductor layers 11r and 11r′may be, for example, N-type impurities such as P or As.

The next step, as shown in FIG. 7B, is to form the wiring layer 14r, which is embedded in the interlayer insulating layer 13r, on the semiconductor layer 11r′. After that, as shown in FIG. 7C, the supporting substrate 15r is adhered onto the interlayer insulating layer 13r.

The next step, as shown in FIG. 8A, is to remove the semiconductor substrate 10r from the semiconductor layer 11r by using CMP or etch-back techniques.

As shown in FIG. 8B, due to the ion implantation in high concentration of impurities on the semiconductor layer 11r, a pinning layer 16r is formed on the semiconductor layer 11r. It should be noted that impurities at this stage may be, for example, P-type impurities such as B. Also, by the epitaxial growth that has been doped by P-type impurities in high concentration, it is also good to form the pinning layer 16r on the back side of the semiconductor layer 11r.

Referring again to FIG. 2C, the next step is to form the on-chip lens 19r in individual pixels after forming the antireflection film 17r on the pinning layer 16r.

### Second Embodiment

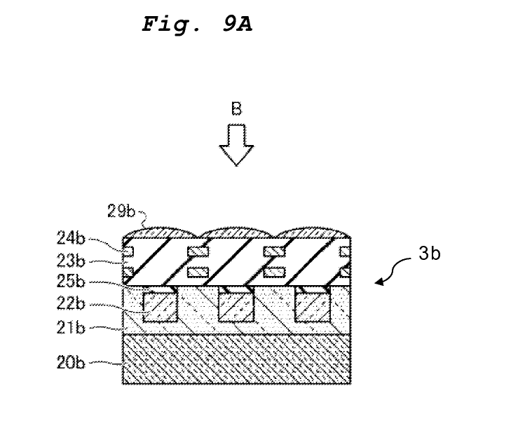

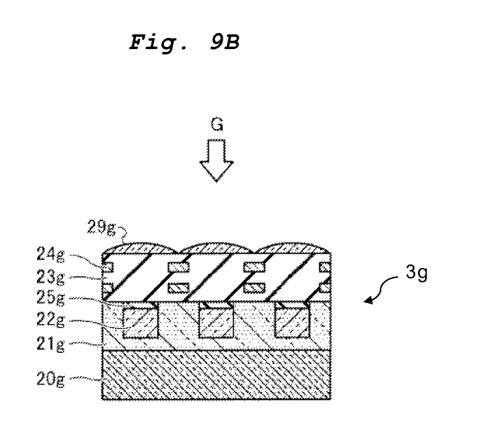

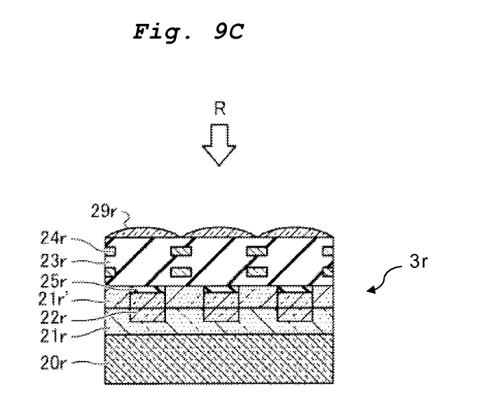

FIG. 9A is a schematic cross-sectional view showing another embodiment of an image sensor 3b for blue color that may be used with the solid-state imaging device of FIG. 1. FIG. 9B is a schematic cross-sectional view showing another embodiment of an image sensor 3g for green color that may be used with the solid-state imaging device of FIG. 1. FIG. 9C is a schematic cross-sectional view showing another embodiment of an image sensor 3r for red color that may be used with the solid-state imaging device of FIG. 1. It should be noted that in FIG. 9A to FIG. 9C, the image sensors 3b, 3g and 3r may be utilized as a front-illuminated type image sensor.

FIG. 9A shows that, in the image sensor 3b for blue color, a semiconductor substrate 20b is provided, and on the semiconductor substrate 20b, a well layer 21b is provided. It should be noted that the semiconductor substrate 20b and the well layer 21b may be made of Si, for example. Also, the conductivity type of the semiconductor substrate 20b may be set as N type. In addition, to form the well layer 21b, a P-type impurity doped layer may be formed on the semiconductor substrate 20b, or a P-type epitaxial semiconductor layer may be formed on the semiconductor substrate 20b. On the front side (i.e., light-incident side) of the well layer 21b, a photoelectric converting layer 22b is formed as individual pixels. On the photoelectric converting layer 22b, a pinning layer 25b is formed. Also, it is possible to set the conductivity type of the photoelectric converting layer 22b as N type. The pinning layer 25b may use a P-type impurities layer formed on the photoelectric converting layer 22b. Also, the well layer 21b may form a potential barrier in order to eliminate cross-talk of the electrical charges formed by other photoelectric conversion in adjacent photoelectric converting layers 22b. An interlayer insulating layer 23b is formed on pinning layer 25b. In the interlayer insulating layer 23b, a wiring layer 24b is embedded. It should also be noted that, for a front-illuminated type image sensor, the wiring layer 24b may be placed in positions to avoid blocking the top of the photoelectric converting layer 22b in order to not interfere with blue light B entering the image sensor 3b and impinging on the photoelectric converting layer 22b. The materials of the wiring layer 24b may be, for example, metals such as Al or Cu. Also, the wiring layer 24b may be used to select the pixels to read out or to transmit the signals that have been read out from pixels. On the interlayer insulating layer 23b, the on-chip lens 29b is formed in individual pixels. The on-chip lens 29b may be, for example, transparent organic compounds such as acrylic materials or polycarbonate materials.

FIG. 9B shows that, in the image sensor 3g for green color, a semiconductor substrate 20g is provided, and on the semiconductor substrate 20g, a well layer 21g is provided. On the front side (i.e., light-incident side) of the well layer 21g, a photoelectric converting layer 22g is formed in individual pixels, and on the top (i.e., light-incident side) of the photoelectric converting layer 22g, a pinning layer 25g is formed. It should be noted that the well layer 21g may form a potential barrier in order to eliminate cross-talk of the electrical charges that have been photoelectrically converted in adjacent photoelectric converting layers 22g. On the pinning layer 25g, an interlayer insulating layer 23g is formed, and in the interlayer insulating layer 23g, a wiring layer 24g is embedded. On the interlayer insulating layer 23g, the on-chip lens 29g is formed in individual pixels. The wiring layer 24g may be positioned intermediate of the photoelectric converting layers 22g to minimize diagonally incident light reaching the photoelectric converting layers 22g.

It should be noted that the well layer 21g, the photoelectric converting layer 22g, the interlayer insulating layer 23g, the wiring layer 24g, the pinning layer 25g and the on-chip lens 29g may respectively use the same materials as the well layer 21b, the photoelectric converting layer 22b, the interlayer insulating layer 23b, the wiring layer 24b, the pinning layer 25b and the on-chip lens 29b.

FIG. 9C shows that, in the image sensor 3r for red color, a semiconductor substrate 20r is provided, and on the semiconductor substrate 20r, a well layer 21r is provided. On the well layer 21r, an alloy semiconductor layer 21r′ is laminated. The alloy semiconductor layer 21r′ may use materials with a higher light absorption coefficient than those of the well layer 21r, such as SiGe. It should be noted that, for lattice matching of Si and SiGe, the content of Ge in SiGe is more than 0% and less than about 30%. As the semiconductor layer 21r′, a P-type epitaxial semiconductor may be used. A photoelectric converting layer 22r is formed in individual pixels on the alloy semiconductor layer 21r′, and on the photoelectric converting layer 22r, a pinning layer 25r is formed. It should be noted that the well layer 21r may form a potential barrier in order to eliminate crosstalk of electrical charges that have been photoelectrically converted in adjacent pixels outside of the photoelectric converting layer 22r. The pinning layer 25r may use P-type impurities layer formed on the alloy semiconductor layer 21r′. On the pinning layer 25r, an interlayer insulating layer 23r is formed, and in the interlayer insulating layer 23r, a wiring layer 24r is embedded. On the interlayer insulating layer 23r, an on-chip lens 29r is formed in individual pixels.

It should be noted that the well layer 21r, the photoelectric converting layer 22r, the interlayer insulating layer 23r, the wiring layer 24r, the pinning layer 25r and the on-chip lens 29r may respectively use the same materials as the well layer 21b, the photoelectric converting layer 22b, the interlayer insulating layer 23b, the wiring layer 24b, the pinning layer 25b and the on-chip lens 29b.

In the structure of FIG. 9C, in order to form the photoelectric converting layer 22r, the method using a two-layer structure—the well layer 21r and the semiconductor layer 21r′—is described, but a one-layer structure may be used, such as a layer consisting of only the semiconductor layer 21r′.

Here, by using the alloy semiconductor layer 21r′ in order to form the photoelectric converting layer 22r, the photoelectric conversion efficiency of the photoelectric converting layer 22r may be improved compared to the technique of forming the photoelectric converting layer 22r by using only the well layer 21r. Thus, it is possible to reduce the depth of the photoelectric converting layer 22r while suppressing a decrease in sensitivity of the image sensor 3r for red color. Additionally, by locating the wiring layer 24r intermediate of the photoelectric converting layers 22r it is possible to suppress the interference of red light R diagonally incident from adjacent pixels, which increases resolution.

As the blue light B and the green light G have shorter wavelengths compared to the red light R, these blue light B and green light G wavelengths reach shallow depths of the photoelectric converting layer 22b and the photoelectric converting layer 22g, respectively. Therefore, by making the depths of the photoelectric converting layer 22b and the photoelectric converting layer 22g shallower in order to meet the depth of the photoelectric converting layer 22r, it is possible to suppress the decrease in sensitivity of the image sensor 3b for blue color and the image sensor 3g for green color.

### Third Embodiment

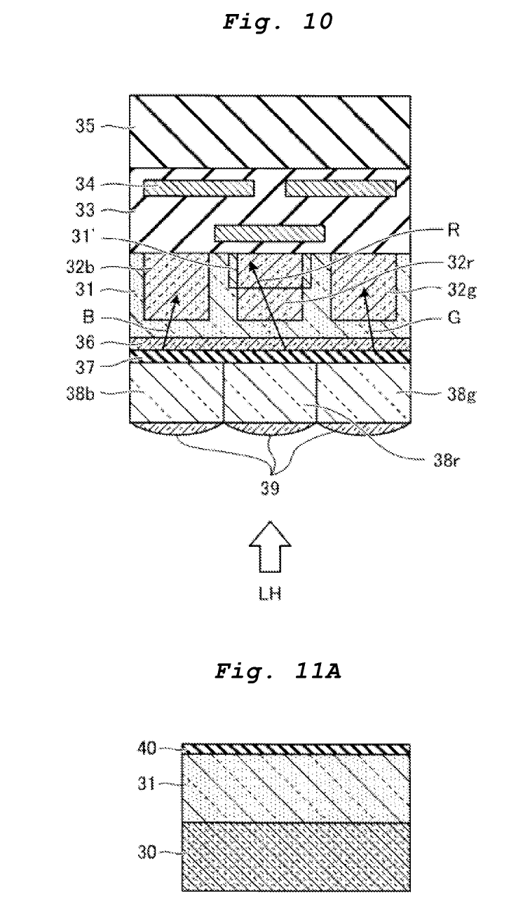

FIG. 10 is a schematic cross-sectional view showing another embodiment of an image sensor that may be used with the solid-state imaging device of FIG. 1. It should be noted that, in the first embodiment as described above, a back-illuminated type image sensor, which is applied as a three-plate type solid-state imaging device, is shown as an example, but in this embodiment, a back-illuminated type image sensor applied as an one-plate type solid-state imaging device will be shown as an example.

FIG. 10 shows that a semiconductor layer 31 is provided on a back-illuminated type image sensor. Photoelectric converting layers 32b, 32r and 32g are formed in individual pixels on a semiconductor layer 31. The semiconductor layer 31 may use Si, for example, as its material. Also, it is possible to use a P-type epitaxial semiconductor as the semiconductor layer 31. In the semiconductor layer 31, an embedded alloy semiconductor layer 31′ is formed in one part of the pixels, such as the photoelectric converting layer 32r. The embedded alloy semiconductor layer 31′ may use materials with a higher light absorption coefficient than those of the semiconductor layer 31, such as SiGe. It should be noted that, in order to take the lattice matching between Si and SiGe, it is preferable that the content of Ge in SiGe is more than 0% and less than about 30%. Also, as the semiconductor layer 31, a P-type epitaxial semiconductor may be used.

While photoelectric converting layers 32b and 32g are formed in individual pixels on the semiconductor layer 31, a photoelectric converting layer 32r, having the embedded alloy semiconductor layer 31′, is formed in individual pixels. It should be noted that the conductivity type of the photoelectric converting layers 32b, 32g and 32r may be set as N type. Also, the thickness of the semiconductor layer 31 may be set in order to prevent cross-talk of electrical charges between the photoelectric converting layers 32b, 32g and 32r of the pixels of the semiconductor layer 31. On the semiconductor layer 31, an interlayer insulating layer 33 is formed. As materials of the interlayer insulating layer 33, for example, a silicon oxide (e.g., SiO₂) film may be used. In the interlayer insulating layer 33, a wiring layer 34 is embedded. It should be noted that, for a back-illuminated type image sensor, the wiring layer 34 may be positioned below the photoelectric converting layers 32b, 32g and 32r (i.e., opposite the light incident side of the photoelectric converting layers 32b, 32g and 32r). As materials of the wiring layer 34, metals such as Al and Cu may be used. Also, the wiring layer 34 may be used in order to select the pixels to read out or to transmit the signals read out from the pixels. On the interlayer insulating layer 33, a supporting substrate 35, which supports the semiconductor layer 31, is provided. The supporting substrate 35 may use a semiconductor substrate such as Si or an insulating substrate such as glass, ceramic or resin.

On the light incident side of the semiconductor layer 31, a pinning layer 36 is formed, and on the pinning layer 36, an antireflection film 37 is formed. It should be noted that the pinning layer 36 may use a P-type layer formed on the semiconductor layer 31. The antireflection film 37 may use the laminated structure of silicon oxide film, which has a different refractive index. On the antireflection film 37, a blue transmission filter 38b, a green transmission filter 38g and a red transmission filter 38r are formed. It is possible to respectively place the blue transmission filter 38b in the path of incident light directed to the photoelectric converting layer 32b, the green transmission filter 38g in the path of incident light directed to the photoelectric converting layer 32g and the red transmission filter 38r in the path of incident light directed to the photoelectric converting layer 32r. On the blue transmission filter 38b, the green transmission filter 38g and the red transmission filter 38r, an on-chip lens 39 is formed in individual pixels. It should be noted that, as the on-chip lens 39, for example, materials comprising transparent organic compounds, such as acrylic or polycarbonate, may be used.

In this embodiment, the alloy semiconductor layer 31′ is used to form the photoelectric converting layer 32r, which enables an increase in photoelectric conversion efficiency of the photoelectric converting layer 32r as compared to using only the semiconductor layer 31 to form the photoelectric converting layer 32r. Consequently, while suppressing the decrease in sensitivity of the photoelectric converting layer 32r, it is possible to reduce the depth of the photoelectric converting layer 32r, which enables the suppression of the interference of red light R, which is incident diagonally in the photoelectric converting layer 32r, in the photoelectric converting layers 32b and 32g. Thus, the mixing of colors may be suppressed.

As the blue light B and the green light G have shorter wavelengths compared to the red light R, the blue light B and green light G wavelengths reach a shallower depth of the photoelectric converting layer 32b and the photoelectric converting layer 32g, respectively. Therefore, by making shallower the depths of the photoelectric converting layer 32b and the photoelectric converting layer 32g in order to meet the depth of the photoelectric converting layer 32r, it is possible to suppress the decrease in sensitivity of photoelectric converting layer 32b and the photoelectric converting layer 32g.

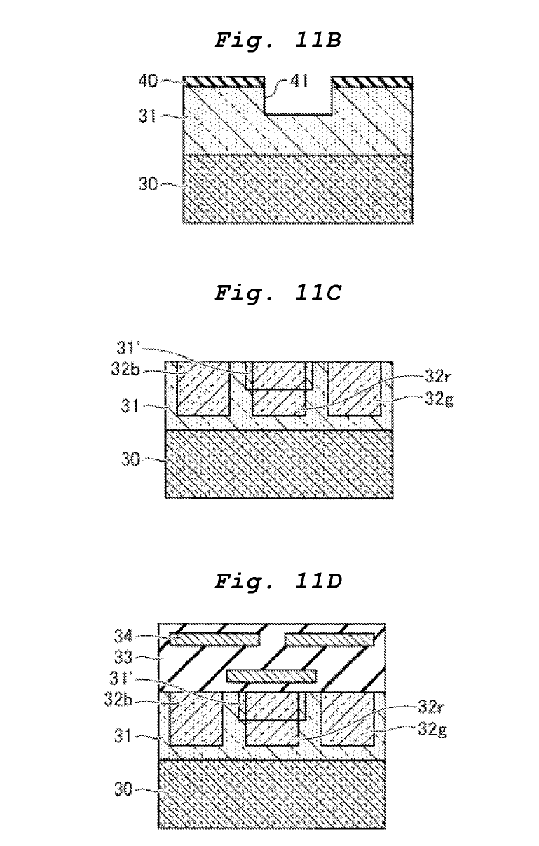

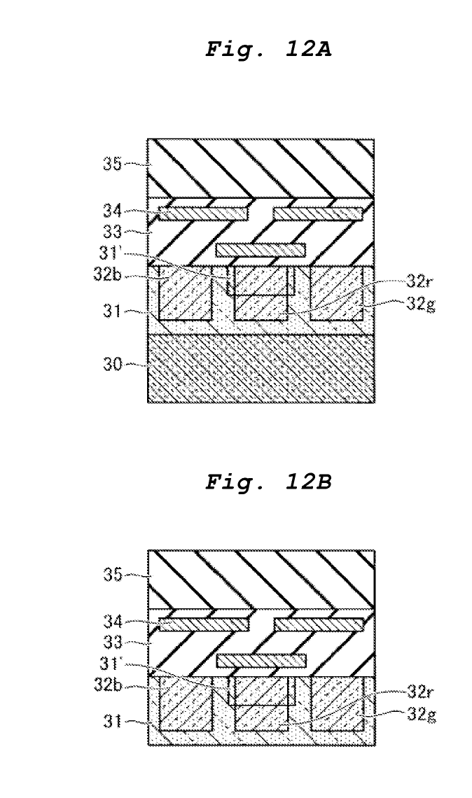

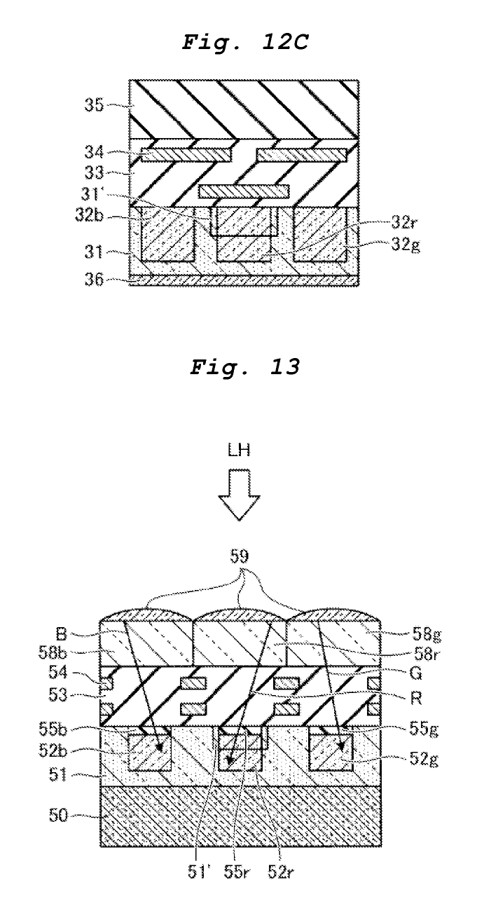

FIG. 11A to FIG. 11D and FIG. 12A to FIG. 12C are cross-sectional views illustrating portions of a manufacturing method of the image sensor in FIG. 10.

FIG. 11A shows that the semiconductor layer 31 is formed on a semiconductor substrate 30 by epitaxial growth. It should be noted that when Si is used as the semiconductor layer 31, it is preferable to use Si for the semiconductor substrate 30 as well. At this stage, P-type impurities such as B may be used to dope the semiconductor layer 31.

After that, an insulating layer 40 is deposited on the semiconductor layer 31 by using techniques such as CVD or thermal oxidation. It should be noted that silicon oxide film, for example, may be used as materials for the insulating layer 40.

The next step, as shown in FIG. 11B, is to form a trench 41 on the semiconductor layer 31 through the insulating layer 40 by using photolithography or a dry etching technique.

As shown in FIG. 11C, due to selective epitaxial growth, the embedded alloy semiconductor layer 31′ is selectively embedded in the trench 41. It should be noted that, when Si is used as the semiconductor layer 31, it is possible to use SiGe as the embedded alloy semiconductor layer 31′. At this stage, P-type impurities such as B may be doped by the embedded alloy semiconductor layer 31′.

After that, in order to selectively implant the impurities in individual pixels, on the semiconductor layer 31 and the embedded alloy semiconductor layer 31′ by using photolithography or ion implantation technique, while forming the photoelectric converting layers 32b and 32g in individual pixels on the front side of the semiconductor layer 31, the photoelectric converting layer 32r is formed in individual pixels on the embedded alloy semiconductor layer 31′. It should be noted that, as impurities at this stage, N-type impurities such as P or A may be used.

As shown in FIG. 11D, the wiring layer 34 embedded in the interlayer insulating layer 33 is formed on the semiconductor layer 31 and on the embedded alloy semiconductor layer 31′. After that, as shown in FIG. 12A, the supporting substrate 35 is pasted on the interlayer insulating layer 33.

As shown in FIG. 12B, by using techniques such as CMP or back etching in order to thin the semiconductor substrate 30, the semiconductor substrate 30 is removed from the back side of the semiconductor layer 31.

The next step, as shown in FIG. 12C, is to perform a high concentration ion implantation of the impurities on the back side of the semiconductor layer 31 in order to form the pinning layer 36 on the same side. It should be noted that impurities at this stage may be P-type impurities such as B. Also, it is good to form the pinning layer 36 on the back side of the semiconductor layer 31 by epitaxial growth that has been highly doped by P-type impurities.

As shown in FIG. 10, after forming the antireflection film 37 on the pinning layer 36, the blue transmission filter 38b, the green transmission filter 38g and the red transmission filter 38r are formed in individual pixels on the antireflection layer 37. At this stage, the blue transmission filter 38b may be placed on the photoelectric converting layer 32b, the green transmission filter 38g on the photoelectric converting layer 32g and the red transmission filter 38r on the photoelectric converting layer 32r. On the blue transmission filter 38b, the green transmission filter 38g and the red transmission filter 38r, the on-chip lens 39 may be formed in individual pixels.

### Fourth Embodiment

FIG. 13 is a cross-sectional view showing schematic configurations of image sensors applied in the solid-state imaging device representing the fourth embodiment. It should be noted that, as described above in the second embodiment, a surface radiation type of image sensor is applied and shown as an example of a three-plate type solid-state imaging device, but in this fourth embodiment, a surface radiation type of image sensor will be applied as an example of a one-plate type solid-state imaging device.

FIG. 13 shows that, on a surface radiation type of image sensor, a semiconductor substrate 50 is provided and on the semiconductor substrate 50, a well layer 51 is provided. It should be noted that Si, for example, may be used as material for the semiconductor substrate 50 and the well layer 51. The conductivity type of the semiconductor substance 50 may be set as N-type. Also, for the well layer 51, it is good to use the P-type impurity diffusion layer formed on the semiconductor substrate 50 or P-type epitaxial semiconductor layer formed on the semiconductor substrate 50. On the well layer 51, an embedded alloy semiconductor layer 51′ is embedded in one part of the pixels. The embedded alloy semiconductor layer 51′ may use materials that have a higher light absorption coefficient than the well layer 51, for example, SiGe may be used. It should also be noted that, in order to take lattice matching between Si and SiGe, the content of Ge in SiGe may be more than 0% and less than 30%. Also, as the embedded alloy semiconductor layer 51′, a P-type epitaxial semiconductor may be used.

On the front side of the well layer 51, while a photoelectric converting layers 52b and 52g are formed in individual pixels, a photoelectric converting layer 52r is formed in individual pixels on the embedded alloy semiconductor layer 51′. It should be noted that the conductivity type of the photoelectric converting layers 52b, 52g and 52r may be set as N-type. Also, the well layer 51 may form a potential barrier in order to prevent the flows of electrical charge that have been photoelectrically converted from outside the photoelectric converting layer 52r into the photoelectric converting layers 52b and 52g. On the photoelectric converting layers 52b, 52g and 52r, pinning layers 55b, 55g and 55r are respectively formed. It should be noted that the pinning layers 55b, 55g and 55r may use P-type impurity layers formed on the photoelectric converting layers 52b, 52g and 52r. On the pinning layers 55b, 55g and 55r, an interlayer insulating layer 53 is formed. The interlayer insulating layer 53 may use, for example, silicon oxide film as its material. On the interlayer insulating layer 53, a wiring layer 54 is embedded. It should be noted that the wiring layer 54 may use metals such as Al or Cu as materials. Also, the wiring layer 54 may be used to select the pixels to read out or to transmit the signals read out from the pixels.

On the interlayer insulating layer 53, a blue transmission filter 58b, a green transmission filter 58g and a red transmission filter 58r are formed. It is possible to place the blue transmission filter 58b on the photoelectric converting layer 52b, the green transmission filter 58g on the photoelectric converting layer 52g and the red transmission filter 58r on the photoelectric converting layer 52r. On the blue transmission filter 58b, the green transmission filter 58g and the red transmission filter 58r, an on-chip lens 59 is formed in individual pixels. It should be noted that, as the on-chip lens 59, for example, transparent organic compounds such as acrylic or polycarbonate may be used.

Here, the embedded alloy semiconductor layer 51′ is used to form the photoelectric converting layer 52r, and this enables an increase in photoelectric conversion efficiency of the photoelectric converting layer 52r compared to when only the well layer 51 is used to form the photoelectric converting layer 52r. Thus, it is possible to reduce the depth of the photoelectric converting layer 52r while suppressing the decrease in sensitivity of the photoelectric converting layer 52r. Reducing the depth of the photoelectric converting layer 52r also enables the suppression of the interference of red light R, which is incident diagonally in the photoelectric converting layer 52r; in the photoelectric converting layers 52b and 52g. Therefore, the mixture of colors may be suppressed.

On the other hand, as the blue light B and the green light G have shorter wavelengths compared to the red light R, the blue light B and green light G reach shallow depths of the photoelectric converting layer 52b and the photoelectric converting layer 52g, respectively. Therefore, by making shallower the depths of the photoelectric converting layer 52b and the photoelectric converting layer 52g in order to meet the depth of the photoelectric converting layer 52r, it is possible to suppress the decrease in sensitivity of the photoelectric converting layer 52b and the photoelectric converting layer 52g.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid-state imaging device, comprising:
a wavelength separator that separates incident light into a first wavelength range, a second wavelength range, and a third wavelength range;
a first image sensor comprising a first photoelectric conversion layer for converting the first wavelength range into an electrical signal;
a second image sensor comprising a second photoelectric conversion layer for converting the second wavelength range into an electrical signal; and
a third image sensor comprising a third photoelectric conversion layer for converting the third wavelength range into an electrical signal, wherein the first photoelectric conversion layer and the second photoelectric conversion layer consist essentially of silicon and the third photoelectric conversion layer comprises an embedded layer comprising an alloy of silicon and germanium.

2. The imaging device of claim 1, wherein the third photoelectric conversion layer consists essentially of silicon.

3. The imaging device of claim 1, wherein the embedded layer is formed at a shallower depth than the first, the second, and the third photoelectric conversion layers.

4. The imaging device of claim 1, wherein the embedded layer comprises a content of germanium that is greater than 0 percent to less than about 30 percent.

5. The imaging device of claim 1, further comprising:
a pinning layer formed between the wavelength separator and the first, the second, and the third photoelectric conversion layers.

6. The imaging device of claim 1, further comprising:
an insulating layer formed on a side of the first, the second, and the third photoelectric conversion layers that is opposite to the wavelength separator, the insulating layer having a wiring layer formed therein.

7. The imaging device of claim 6, further comprising:
a filter disposed between the wavelength separator and the insulating layer.

8. The imaging device of claim 6, wherein the wiring layer is positioned intermediate of each of the first, the second, and the third photoelectric conversion layers.

9. A solid-state imaging device, comprising:
a semiconductor layer having a first light absorption coefficient;
an embedded semiconductor layer that is formed on the semiconductor layer having a second light absorption coefficient that is different than the first light absorption coefficient;
a first photoelectric conversion layer comprising a first pixel on the semiconductor layer;
a second photoelectric conversion layer comprising a second pixel adjacent the embedded semiconductor layer;
a third photoelectric conversion layer comprising a third pixel on the semiconductor layer;
a first color filter to transmit wavelengths associated with a first color light into the first photoelectric conversion unit;
a second color filter to transmit wavelengths associated with a second color light into the second photoelectric conversion unit; and
a third color filter to transmit wavelengths associated with a third color light into the third photoelectric conversion unit.

10. The imaging device of claim 9, wherein the embedded semiconductor layer comprises an alloy of silicon and germanium.

11. The imaging device of claim 10, wherein the embedded semiconductor layer comprises a content of germanium that is greater than 0 percent to less than about 30 percent.

12. The imaging device of claim 10, wherein the semiconductor layer consists essentially of silicon.

13. The imaging device of claim 10, wherein one or a combination of the first, the second, and the third photoelectric conversion layers consist essentially of silicon.

14. The imaging device of claim 10, wherein the embedded semiconductor layer is formed at a shallower depth than the first, the second, and the third photoelectric conversion layers.

15. A method for manufacturing a solid-state imaging device, the method comprising:
forming semiconductor layer on a substrate, the semiconductor layer consisting essentially of silicon;
oxidizing a portion of the semiconductor layer to form a first insulating layer on the semiconductor layer;
forming a trench in the first insulating layer and the semiconductor layer;
removing the first insulating layer;
selectively forming an alloy layer comprising silicon and germanium in the trench;
selectively implanting the semiconductor layer to form photoelectric conversion layers adjacent to the alloy layer;
forming a second insulating layer on the semiconductor layer, the second insulating layer comprising a wiring layer;
adhering a supporting substrate to the second insulating layer;
removing the substrate; and
forming a filter layer on the semiconductor layer.

16. The method of claim 15, wherein the alloy layer comprises a content of germanium that is greater than 0 percent to less than about 30 percent.

17. The method of claim 15, further comprising forming a pinning layer on the semiconductor layer prior to forming the filter layer.

18. The method of claim 17, further comprising forming an anti-reflective film on the pinning layer.

19. The method of claim 18, further comprising forming a lens on the anti-reflective film.

20. The method of claim 15, wherein the wiring layer is disposed intermediate of the photoelectric converting layers.
